(19) United States
(12) Patent Application Publication
(10) Pub. No.: US 2020/0375036 A1
(43) Pub. Date: Nov. 26, 2020

(54) METHOD OF ENHANCING ELECTRICAL CONNECTIONS IN 3D-PRINTED OBJECTS

(71) Applicant: SIGNIFY HOLDING B.V., EINDHOVEN (NL)

(72) Inventors: RIFAT ATA MUSTAFA HIKMET, EINDHOVEN (NL); TIES VAN BOMMEL, HORST (NL)

(73) Assignee: SIGNIFY HOLDING B.V., EINDHOVEN (NL)

(21) Appl. No.: 16/496,471

(22) PCT Filed: Mar. 20, 2018
(86) PCT No.: PCT/EP2018/056923

§ 371 Date: Sep. 23, 2019

(30) Foreign Application Priority Data
Mar. 28, 2017 (EP) 17163230.0

(51) Int. Cl. H05K 3/32; H05K 1/18

(52) U.S. Cl. CPC H05K 3/326; H05K 2203/0278; H05K 1/185

(57) ABSTRACT

There is provided an electrical arrangement (100), comprising at least one electrical unit (110), which in its turn comprises electrical element(s) (120) with electrical contact point(s) (130a, 130b) and electrically conductive track(s) (140a, 140b) arranged in contact with the electrical contact point(s) of the electrical element(s). The electrical arrangement further comprises a substrate (145), N for supporting the electrical unit, and component(s) (120) for connecting portions of the substrate. The material of the component(s) is resizable upon processing of the material, such that, upon processing of the component(s), at least one of the electrical element(s) and the electrically conductive track(s) of the electrical unit(s) are squeezed at the respective electrical contact point by the first and second portions of the substrate biased by the force from the component(s).

### FIELD OF THE INVENTION

The present invention generally relates to the field of 3D printing. More specifically, the present invention relates to methods of enhancing electrical connections in 3D-printed objects, to an electrical arrangement obtainable by such methods, to a 3D-printing apparatus for performing such methods, and to a computer program product comprising instructions which, when the computer program product is executed by the 3D printing apparatus, cause the 3D printing apparatus to carry out such methods.

### BACKGROUND OF THE INVENTION

Additive manufacturing, sometimes also referred to as 3D printing, refers to processes used to synthesize a three-dimensional object. 3D printing is rapidly gaining popularity because of its ability to perform rapid prototyping without the need for assembly or molding techniques to form the desired article.

By using a 3D-printing apparatus, an article or object may be built in three dimensions in a number of printing steps that often are controlled by a computer model. For example, a sliced 3D model of the object may be provided in which each slice is recreated by the 3D printing apparatus in a discrete printing step.

One of the most widely used 3D-printing processes is Fused Filament Fabrication (FFF). FFF printers often use a thermoplastic filament which in its molten state is ejected from a nozzle of the printer. The material is then placed layer by layer, to create a three-dimensional object. FFF printers are relatively fast and can be used for printing objects of various kinds, even those having relatively complex structures. It will be appreciated that the FFF process is highly suitable for producing luminaires and parts to be used in lighting applications.

Apart from printing various shapes of the desired object using various polymers, 3D-printing apparatuses may also be used in the production of LED luminaires and lighting solutions. For example, it is desirable to be able to integrate electrically conductive tracks and connect them to electrical components such as LEDs and passive components such as resistors, capacitors, etc. It will be appreciated that electrically conductive tracks can be produced in various ways by 3D-printing apparatuses.

US 2016/0197417 discloses means for facilitating transmission of electrical signals and power between a3D-printed part and another part (which may also be a 3D-printed part). This may for example by achieved by inserting electrically conductive magnets in sockets formed in each of the 3D-printed parts during 3D printing, by inserting electrically conductive magnets in sockets formed in a first part and inserting a biasable, electrically conductive object in the sockets formed in a second part during 3D printing, by 3D printing an electrically conductive feature having a biasable face in a first part and forming an electrically conductive pad/socket on a second part, or by affixing a printed circuit board in a first part and connecting the first part to a second part having contact pins and contact pads formed in the second part.

US-2001/036718 discloses conductive elements that have been manufactured by means of stereolithography, a form of 3D printing. The conductive elements include multiple superimposed, contiguous, mutually adhered layers of a conductive material, such as a thermoplastic conductive elastomer or a metal. In semiconductor device assemblies, the stereolithographically fabricated conductive elements electrically connect semiconductor device components to one another. The conductive elements alternatively comprise conductive traces or vias of circuit boards or interposers.

However, it is rather difficult to obtain a reliable electrical connection between the tracks and the components.

Hence, alternative solutions are of interest, which are able to provide electrical arrangements wherein a reliable electrical connection between electrical tracks and electrical components may be achieved.

### SUMMARY OF THE INVENTION

It is an object of the present invention to mitigate the above problems and to provide an electrical arrangement, e.g. produced at least partially by a 3D-printing apparatus, wherein the electrical connection(s) between one or more electrical tracks and one or more electrical components may be improved.

This and other objects are achieved by providing methods of producing an electrical arrangement, by providing an electrical arrangement obtainable by such methods, and by providing a 3D-printing apparatus for performing such methods, having the features as defined in the independent claims. Preferred embodiments are defined in the dependent claims.

According to a first aspect of the present invention, there is provided a method of producing an electrical arrangement, wherein the method comprises the steps of (a) printing, by a 3D-printing process, a first portion of a substrate, wherein the first portion of the substrate is arranged to support at least one electrical element, (b) providing at least one first part of at least one component at least partially within the first portion, wherein the at least one component comprises a material that is contractible upon processing of the material, (c) arranging at least one electrical element, comprising at least one electrical contact point, at least partially within the first portion of the substrate, (d) printing, by a 3D-printing process, at least one electrically conductive track arranged in contact with the at least one electrical contact point of the at least one electrical element, (e) printing, by a 3D-printing process, a second portion of a substrate, and arranging the second portion at least partially upon the at least one electrically conductive track, (f) providing at least one second part of the at least one component at least partially within the second portion, (g) connecting the first and second parts of the at least one component, and (h) processing the at least one component such that the at least one electrical element and the at least one electrically conductive track of the electrical unit are squeezed at the respective electrical contact point by the first and second portions biased by a force resulting from the contraction of the material of the at least one component.

According to a second aspect of the present invention, there is provided a method of producing an electrical arrangement, wherein the method comprises the steps of (a) printing, by a 3D-printing process, a first portion of a substrate, wherein the first portion of the substrate is arranged to support at least one electrical element, (b) arranging at least one electrical element, comprising at least one electrical contact point, at least partially within the first portion of the substrate, (c) printing, by a 3D-printing process, at least one electrically conductive track arranged in contact with the at least one electrical contact point of the at least one electrical element, (d) arranging at least one component at least partially upon the at least one electrical element, wherein the at least one component comprises a material that is expandable upon processing of the material, (e) printing, by a 3D-printing process, a second portion of a substrate, and arranging the second portion at least partially upon the at least one component, (f) arranging the first and second portions such that upon processing the at least one component the first and second portions become biased by a force resulting from the expansion of the material of the at least one component, and (g) processing the at least one component such that the at least one electrical element and the at least one electrically conductive track of the electrical unit are squeezed at the respective electrical contact point by the force resulting from the expansion of the material of the at least one component.

In the methods according to the first and second aspects of the invention, the step of processing the at least one component may comprise at least one of (a) a cooling of the at least one component, and (b) a polymerization of the at least one component.

According to a third aspect of the present invention, there is provided an electrical arrangement obtainable by the method according to the first aspect of the invention or by the method according to the second aspect of the invention, wherein the electrical arrangement comprises at least one electrical unit. The electrical arrangement further comprises a substrate supporting the electrical unit, wherein the substrate comprises first portion and a second portion arranged on opposite sides, respectively, of the electrical unit. Furthermore, the electrical arrangement comprises at least one component arranged for connecting the first portion and the second portion. The electrical unit comprises at least one electrical element having at least one electrical contact point, and at least one electrically conductive track contacting the electrical contact point. The component comprises a material that is obtainable by processing a resizable material. Either the component is in contact with the first portion and the second portion, in which case the material of the component is obtainable by processing a contractible material, or the component is in contact with the electrical unit, and with at least one of the first portion and the second portion, in which case the material of the component is obtainable by processing an expandable material. At least one of the electrical element and the electrically conductive track are squeezed at the respective electrical contact point by the first portion and the second portion biased by a force from the component, wherein the force is obtainable by processing the resizeable material.

According to a fourth aspect of the present invention, there is provided a 3D-printing apparatus, comprising a first printing material, a second printing material, and at least one printer head, configured to deposit the first printing material and the second printing material. The at least one printer head is configured to construct the substrate of the electrical arrangement in the third aspect of the present invention by depositing at least a portion of the first printing material. Furthermore, the at least one printer head is configured to construct the at least one component of the electrical arrangement in the third aspect of the present invention by depositing at least a portion of the second printing material. The second material of the at least one component is resizeable upon processing of the second material, such that upon a processing of the substrate and the at least one component, the at least one component is configured to resize to a higher extent than the substrate.

According to a fifth aspect of the invention, there is provided a computer program product comprising instructions which, when the computer program product is executed by the 3D printing apparatus according to the fourth aspect of the invention, cause the 3D printing apparatus to carry out the method according to the first aspect of the invention, or according to the second aspect of the invention.

Thus, the present invention is based on the idea of providing an electrical arrangement, wherein a substrate at least partially encloses electrical component(s) and electrically conductive track(s). One or more components of the electrical arrangement are resizable, i.e. contractible or expandable, when subjected to a suitable processing of the component material. Consequently, the electrical component(s) and electrically conductive track(s) are squeezed together by the force from the resizable component(s), resulting in a reliable electrical connection between the electrical track(s) and the electrical component(s). In other words, the present invention provides a substantially permanent pressure between the contact points of the components and the conductive tracks.

In case one or more elements of the electrical arrangement are constructed by a printing material, printed by a 3D-printing apparatus, it is generally not preferred to use a printing material which is shrinkable (contractible) or expandable. However, such a material in the form of a component can be applied locally in areas of an electrical unit wherein pressure is needed for a reliable electrical conduction. The present invention is advantageous in that a relatively convenient and uncomplicated processing of the component(s) of the electrical arrangement may lead to an improved electrical connection between electrical track(s) and electrical component(s) of the electrical arrangement.

The electrical arrangement comprises one or more electrical units. The electrical arrangement further comprises a substrate supporting the electrical unit. By the term “substrate”, it is hereby meant substantially any element for supporting the electrical unit, wherein the substrate may be produced by a printing material from a 3D-printing apparatus. The substrate comprises first and second portions arranged on opposite sides, respectively, of the electrical unit. It will be appreciated that the first and second portions may be unitary or formed as two separate pieces.

The electrical unit comprises an electrical element comprising an electrical contact point. By the term “electrical contact point”, it is hereby meant a point for electrical supply to and from the electrical component(s). One or more electrically conductive tracks are contacting the electrical contact point(s) of the electrical element(s). By the term “electrically conductive tracks”, it is hereby meant electrical lines, connections, or the like, for an electrical supply to and from the electrical component(s), via the electrical contact points.

The electrical arrangement comprises at least one component for connecting the first and the second portion. The material of the component is resizable upon processing of the material. By the term “resizable”, it is hereby meant the material may be either enlarged (e.g. expanded) or shrunk (e.g. contracted) after subjecting the material to a suitable process. By processing the component(s), at least one of the electrical element and the electrically conductive track of the electrical unit are squeezed at the respective electrical contact point by the first and second portions biased by the force from the component. Hence, as the component(s) may be either contracted or expanded as a result of the processing, the first and second portions of the substrate squeeze or clamp the electrical element(s) towards the electrically conductive track(s), or vice versa, at the contact point(s).

According to an embodiment of the present invention, the resizable material of the component is contractible. Hence, when the component material is processed, i.e. subjected to a suitable process, it contracts and/or shrinks

According to an embodiment of the present invention, the substrate comprises a first material having at least one of a first melting temperature, Tₘ₁, and a first glass transition temperature, T_{g1}, and the at least one component comprises a second material having at least one of a second melting temperature Tₘ₂ and a second glass transition temperature, T_{g2}, wherein Tₘ₁>Tm₂, Tm₁>T_{g2}, T_{g1}>Tₘ₂ and T_{g1}>T_{g2}. By “glass transition temperature”, it is here meant the temperature at which a glass transition occurs, i.e. the reversible transition in amorphous materials (or in amorphous regions within semi-crystalline materials) from a solid state into a liquid state as the temperature is increased. The present embodiment is advantageous in that the component(s) comprising the second material, which material is contractible, has a lower transition temperature than the first material, such that the first and second portions of the substrate squeeze or clamp the electrical element(s) towards the electrically conductive track(s) at the contact point(s).

According to an embodiment of the present invention, the first and second portions are arranged along an axis (z), and wherein, for each electrical unit, at least one component is provided adjacent the electrical unit along an axis (x) perpendicular to the first axis (z).

According to an embodiment of the present invention, only one component is provided adjacent each electrical unit. The present embodiment is advantageous in that the structure of the electrical arrangement is easily fabricated.

According to an embodiment of the present invention, at least one component is provided adjacent each electrical unit and on either side of each electrical unit. The present embodiment is advantageous in that a structure of this kind may provide a relatively homogeneous pressure onto the electrical connection. Furthermore, by using more than a component on either side of each electrical unit, e.g. four components per electrical unit, a structure of this kind may provide a relatively high pressure onto the electrical unit.

According to an embodiment of the present invention, at least one of the at least one component protrudes the substrate and has the shape of a barbell, arranged to squeeze the first and second portions of the substrate. The present embodiment is advantageous in that the ends of the barbell shape of the components efficiently squeeze the substrate.

According to an embodiment of the present invention, at least one of the at least one component is shaped as a staple which is arranged to squeeze the first and second portions of the substrate. The present embodiment is advantageous in that the substrate hereby may be efficiently clamped by the staple-shaped component(s).

According to an embodiment of the present invention, the material of the at least one component is expandable. The present embodiment is advantageous in that the components(s) hereby may apply pressure on the electrical unit(s) in an efficient manner. It will be appreciated that the electrical arrangement may comprise only one component. Alternatively, the electrical arrangement may comprise a plurality of components.

According to an embodiment of the of the present invention, the step of processing the at least one component comprises at least one of a cooling of the at least one component, and a polymerization of the at least one component.

Further objectives of, features of, and advantages with, the present invention will become apparent when studying the following detailed disclosure, the drawings and the appended claims. Those skilled in the art will realize that different features of the present invention can be combined to create embodiments other than those described in the following.

### BRIEF DESCRIPTION OF THE DRAWINGS

This and other aspects of the present invention will now be described in more detail, with reference to the appended drawings showing embodiment(s) of the invention.

FIGS. 1a and 1b are schematic views of electrical arrangements according to exemplifying embodiments of the present invention,

FIGS. 2a-g are schematic views of electrical arrangements according to exemplifying embodiments of the present invention,

FIG. 3 is a schematic view of elements of a 3D-printing apparatus according to an exemplifying embodiment of the present invention,

FIGS. 4a-g are schematic views of electrical arrangements according to exemplifying embodiments of the present invention, and

FIGS. 5a-f and 6a-f are schematic views of methods according to exemplifying embodiments of the present invention.

### DETAILED DESCRIPTION

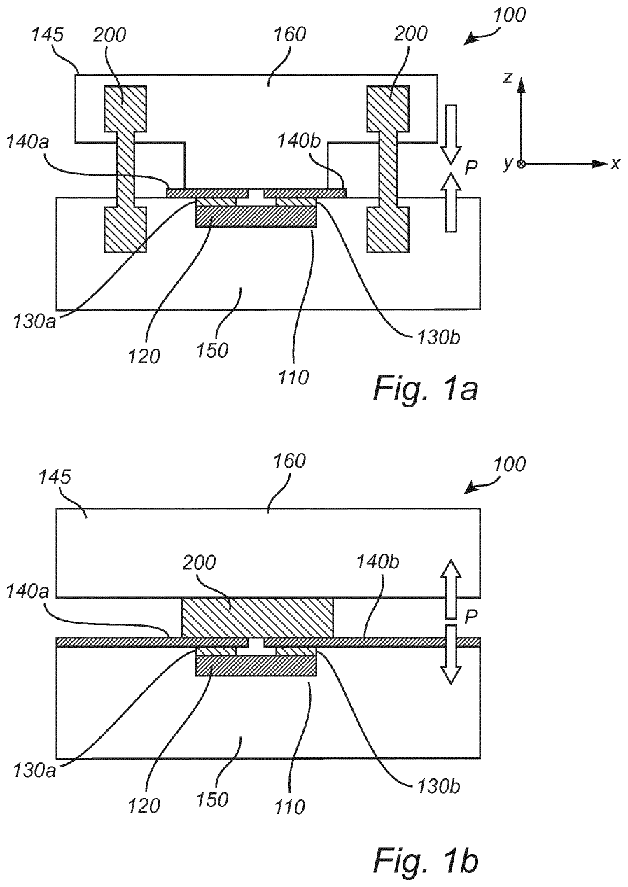

FIG. 1a is a schematic view of an electrical arrangement 100. The electrical arrangement 100 comprises an electrical unit 110, which in its turn comprises an electrical element 120. For example, the electrical element 120 may be a solid state light source, e.g. a light emitting diode (LED), a laser diode, and/or an organic light emitting diode (OLED). The electrical element 120 may also constitute a plurality of solid state light sources arranged on a carrier, e.g. a printed circuit board (PCB). The electrical element 120 may alternatively be a sensor such as a temperature sensor, an optical sensor, a humidity sensor, or the like. The electrical element 120 may alternatively be a photo voltaic cell or a battery.

The electrical unit 110 comprises two electrical contact points 130a, 130b and two electrically conductive tracks 140a, 140b arranged in contact with the respective electrical contact point 130a, 130b. The electrically conductive tracks 140a, 140b may, for example, comprise one or more wires, metal (e.g. copper), aluminum graphite tracks on a foil, etc.

The electrical arrangement 100 further comprises a substrate arranged to support the electrical unit 110. The substrate, which may be 3D-printed (i.e. comprising a printing material such as a polymer), comprises first 150 and second 160 portions arranged on opposite sides, respectively, of the electrical unit 110. Here, the first 150 and second 160 portions are arranged along a vertical axis z, wherein the first portion 150 is arranged below the electrical unit 110, and the second portion 160 is arranged on top of the electrical unit 110. A respective component 200 of a resizable material is provided adjacent and on either side of the electrical unit 110 along an axis x perpendicular to the vertical axis z. The components 200 are integrated into the first 150 and second 160 portions of the substrate 145. Here, the components 200 have the shape of a barbell, wherein the larger end portions are integrated into the first 150 and second 160 portions of the substrate 145.

In this embodiment of the electrical arrangement 100, the resizable material of the component 200 is contractible (shrinkable) upon processing of the material. The processing may include a cooling of the of the material of the component 200. Alternatively, in case the component material is a polymer, the processing may include a polymerization of the material of the component 200. Whereas the substrate may comprise a first material having a first glass transition temperature, T_{g1}, the component 200 may comprise a second material having a second glass transition temperature T_{g2}, wherein T_{g1}>T_{g2} and/or Tₘ₁>Tₘ₂. More specifically, in case the second material is an amorphous polymer and the substrate is an amorphous polymer, the relationship between the first and second glass transition temperatures may be T_{g1}>T_{g2}. In case the second material is an amorphous polymer and the substrate is a semi-crystalline polymer, the relationship between the melting temperature of the first material and the second glass transition temperature may be Tₘ₁>T_{g2}. Furthermore, in case the second material is a crystalline polymer and the substrate is an amorphous polymer, the relationship between the first glass transition temperature and the melting temperature of the second material may be T_{g1}>Tₘ₂. In case the second material is a crystalline polymer and the substrate is a semi-crystalline polymer, the relationship between the melting temperatures of the first and second materials may be Tₘ₁>Tₘ₂. The first material may comprise one or more materials selected from the group consisting of polycarbonate (PC), polysulfone (PSU), polyphenylen sulfide (PPS), high 83C modified polycarbonate copolymer (APEC-1895 Coestro), polybutylene terephthalate (PBT), crystalline polyethylene terephthalate (PET), polyethylene naphthalate (PEN), and polyether ether ketone (PEEK). The second material may comprise one or more materials selected from the group consisting of amorphous polyethylene terephthalate (PET), acrylonitrile butadiene styrene (ABS), poly(methyl methacrylate) PMMA, polystyrene (PS), styrene methylmethacrylate, methylmethacrylate acrylonitrile butadiene styrene (MABS), and styrenic block copolymer (SBC).

Consequently, upon processing of the component(s) 200, the electrical element 120 and the electrically conductive track 140a, 140b of the electrical unit 110 are squeezed at the respective electrical contact point 130a, 130b by the first 150 and second 160 portions biased by the force from the component(s) 200. Hence, there is a resulting pressure P from the first 150 and second 160 portions of the substrate 145, resulting in a more reliable electrical connection of the electrical unit 110.

FIG. 1b is a schematic view of an electrical arrangement 100 similar to that shown in FIG. 1a. It will be appreciated that the first 150 and second 160 portions of the substrate may be mechanically connected (not shown). Here, in contrast to FIG. 1a, the component 200 is expandable, such that the pressure P is induced onto the first 150 and second 160 portions of the substrate 145 from the component 200. Consequently, a more reliable electrical connection of the electrical unit 110 is achieved. It will be appreciated that the process for expanding the component 200 may comprise a swelling of the (polymeric) material of the component 200. Alternatively, the process for expanding the component 200 may comprise thermally expanding the material of the component 200. Hence, the material of the component 200 may comprise a rubber material which can expand (swell), e.g. by adding a polymerizable monomer into the material which can be polymerized in situ to permanently fix the expanded component 200.

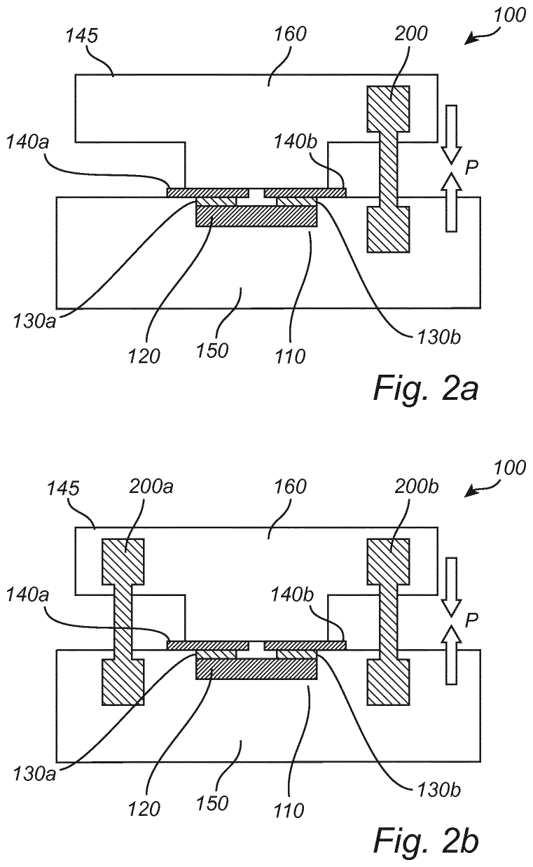

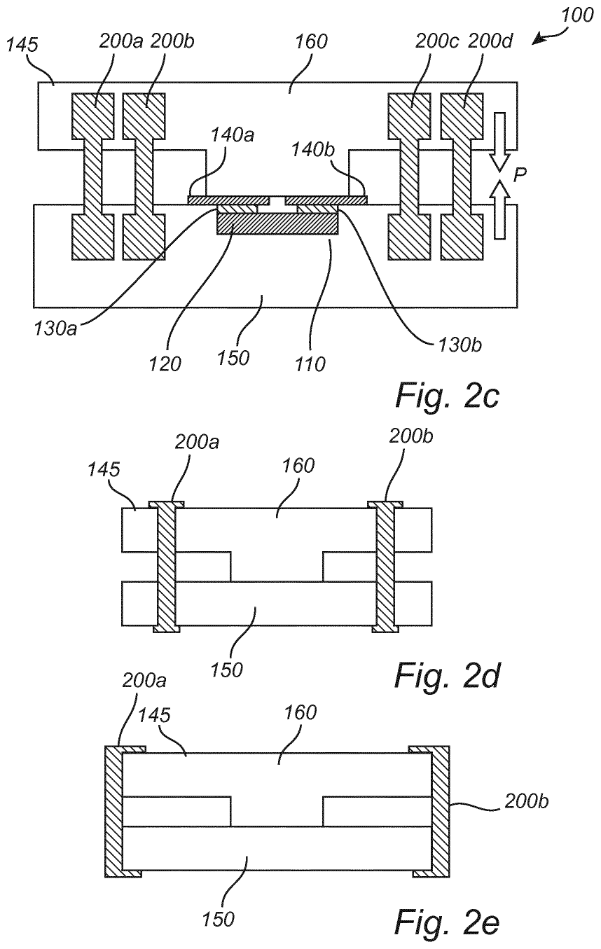

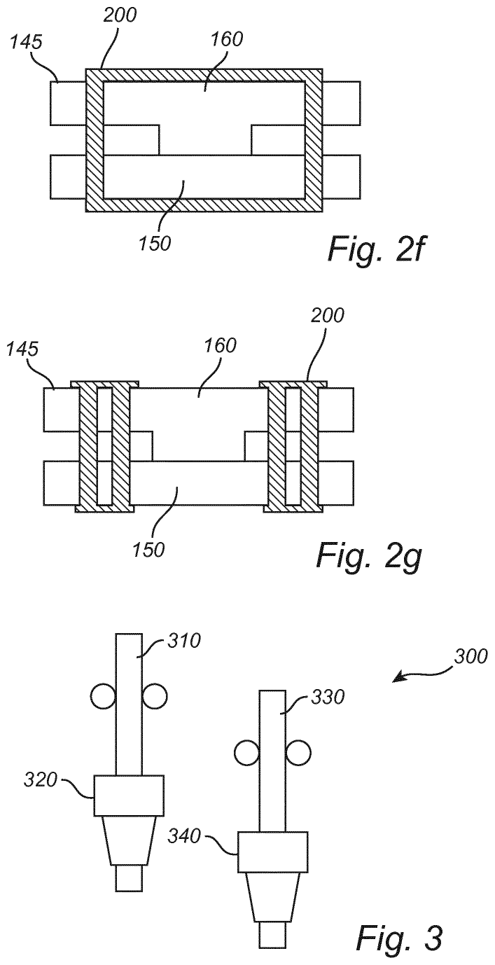

FIGS. 2a-2g show embodiments of electrical arrangements 100 comprising alternative structures to the electrical arrangement 100 of FIG. 1a, wherein the resizable component 200 is shrinkable (contractible). For simplicity, some references have been omitted, and it is referred to FIG. 1a.

According to the example of the electrical arrangement 100 in FIG. 2a, only one component 200 is provided adjacent the electrical unit 110. In FIG. 2b, a component 200a is provided adjacent the electrical unit 110 and on the left hand side of the electrical unit 110, whereas a component 200b is provided adjacent the electrical unit 110 and on the right hand side of the electrical unit 110. Furthermore, in FIG. 2c, four components 200a-d are provided, wherein two components thereof are arranged on either side of the electrical unit 110.

In FIG. 2d, there are provided two barbell-shaped components 200a, 200b, arranged on either side of the electrical unit, wherein the components 200a, 200b protrude the substrate. In FIG. 2e, two components 200a, 200b are shaped as a staples and are arranged on peripheral side portions of the electrical arrangement. The components 200a, 200b are hereby arranged to squeeze the first and second portions of the substrate. Furthermore, the component 200 may have the form of a band, as exemplified in FIG. 2f. As yet another alternative, there may be a plurality of components 200 shaped as ribs, as shown in FIG. 2g.

FIG. 3 shows a schematic view of elements of a 3D-printing apparatus 300. The 3D-printing apparatus comprises a first printing material 310 and a first printer head 320, configured to deposit the first printing material 310. Analogously, there is provided a second printing material 330 and a second printer head 340, configured to deposit the second printing material 330. The first printer head 320 is configured to construct the substrate of the electrical arrangement of any one of the previously described embodiments by depositing at least a portion of the first printing material 310. The second printer head 340 is configured to construct the component(s) of the electrical arrangement of any one the previously described embodiments wherein the component material is shrinkable, by depositing at least a portion of the second printing material 330. It will be appreciated that it is also possible to use a single printer head being configured to print the first and the second printing material from the same printer head. The material 330 of the at least one component is contractible upon processing of the second material, such that upon a processing of the substrate and the at least one component, the at least one component is configured to contract to a higher extent than the substrate. It will be appreciated that the processing may include a cooling of the of the material of the component and/or a polymerization of the material of the component.

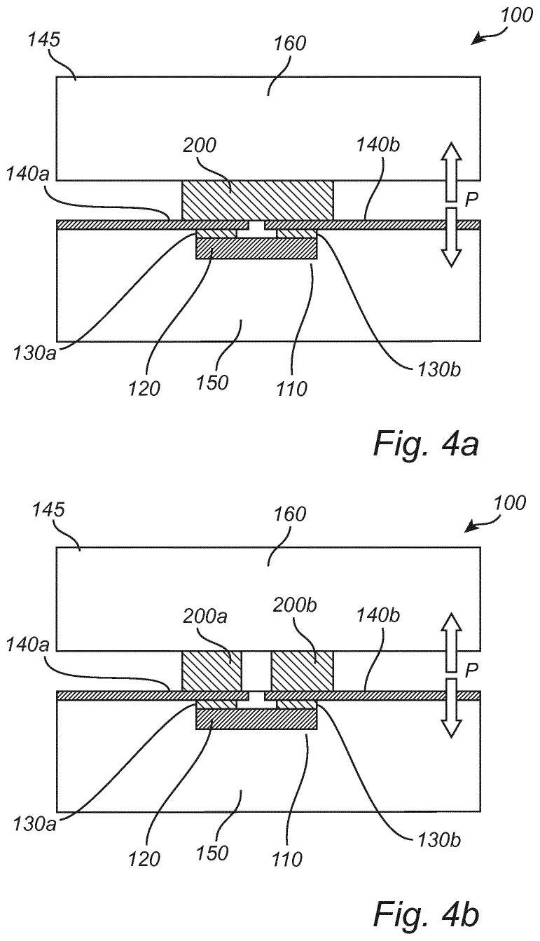

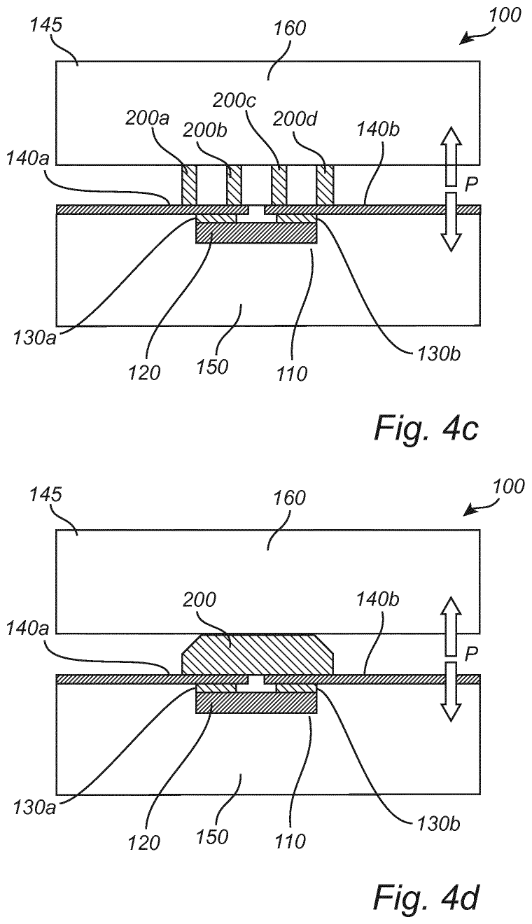

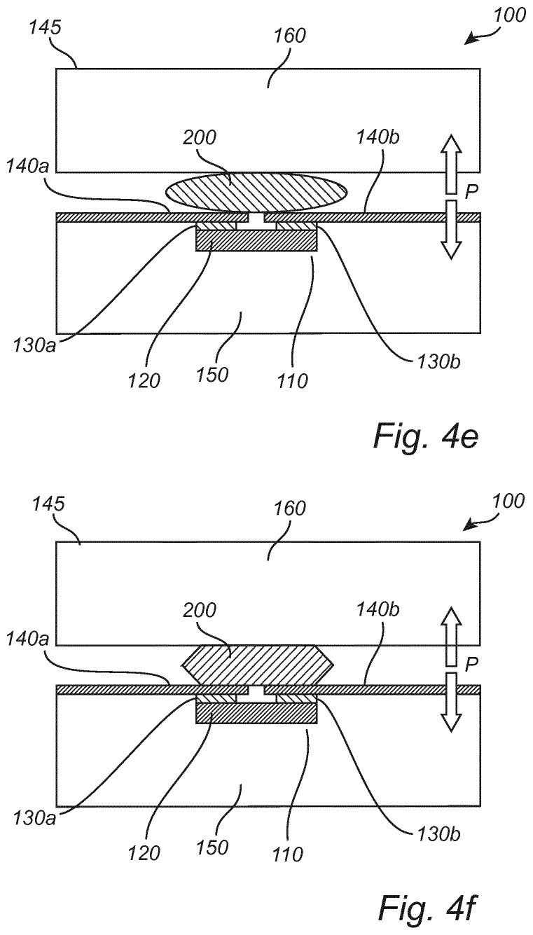

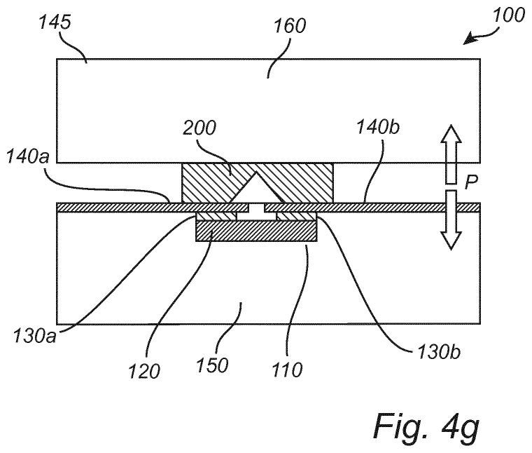

FIGS. 4a-4g show schematic views of embodiments of the electrical arrangement 100 of FIG. 1b, wherein the component 200 is expandable. In FIG. 4a, only one component 200 is provided, formed as a rectangular parallelepiped (i.e. brick-shaped component 200), wherein the component 200 overlaps both contact points 130a, 130b. In FIG. 4b, there are provided two components 200a, 200b, arranged on top of the respective contact point 130a, 130b. Alternatively, as shown in FIG. 4c, there are provided four components 200a-d.

It will be appreciated that the expandable component 200 may have various designs and/or shapes. For example, the component 200 may have the shape of a bar (FIG. 4d), an oval (FIG. 4e), or a polygon (FIG. 4f). Furthermore, the expandable component 200 may comprise multiple ribs (FIG. 4g).

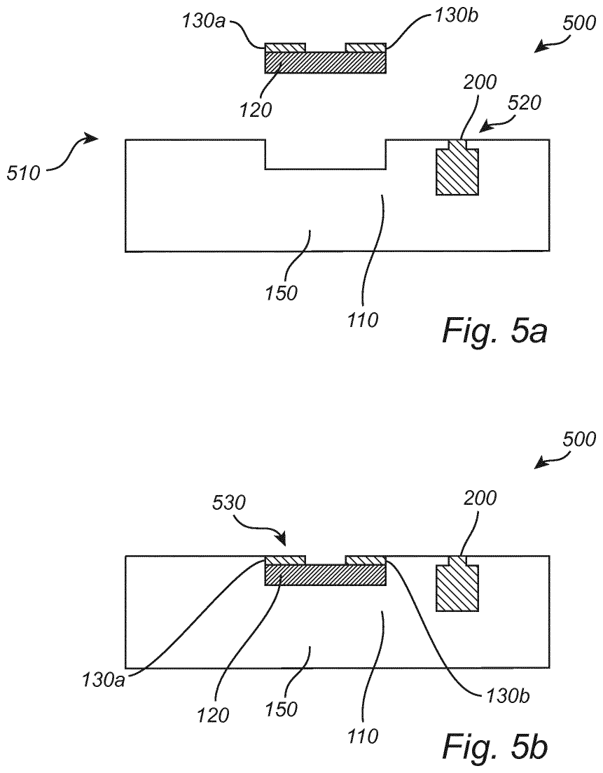

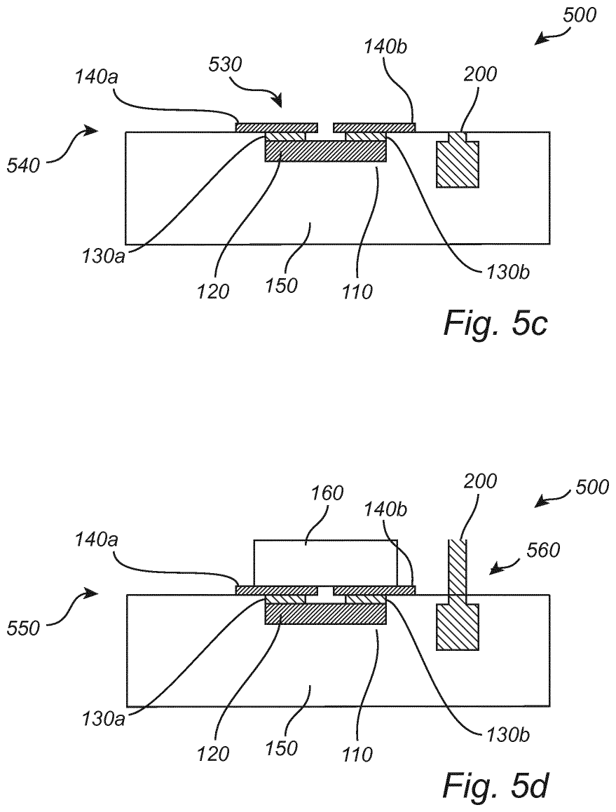

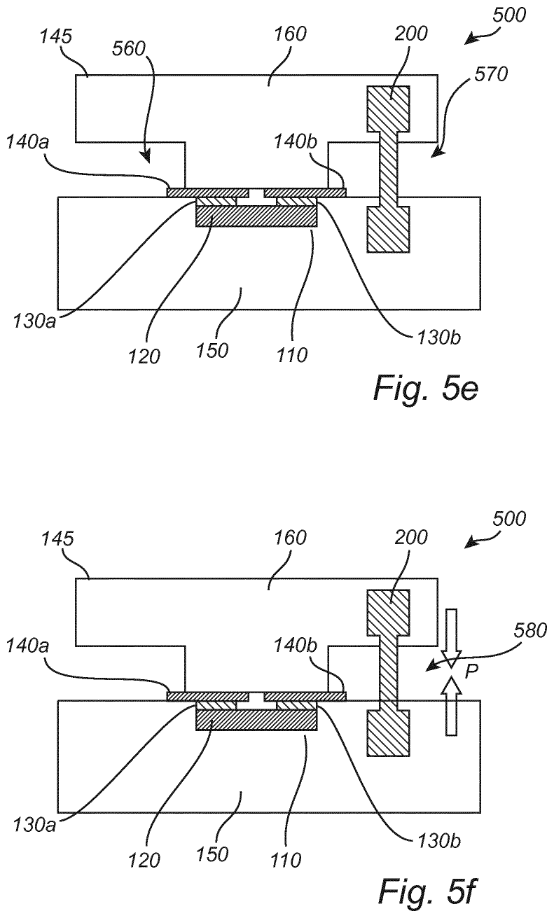

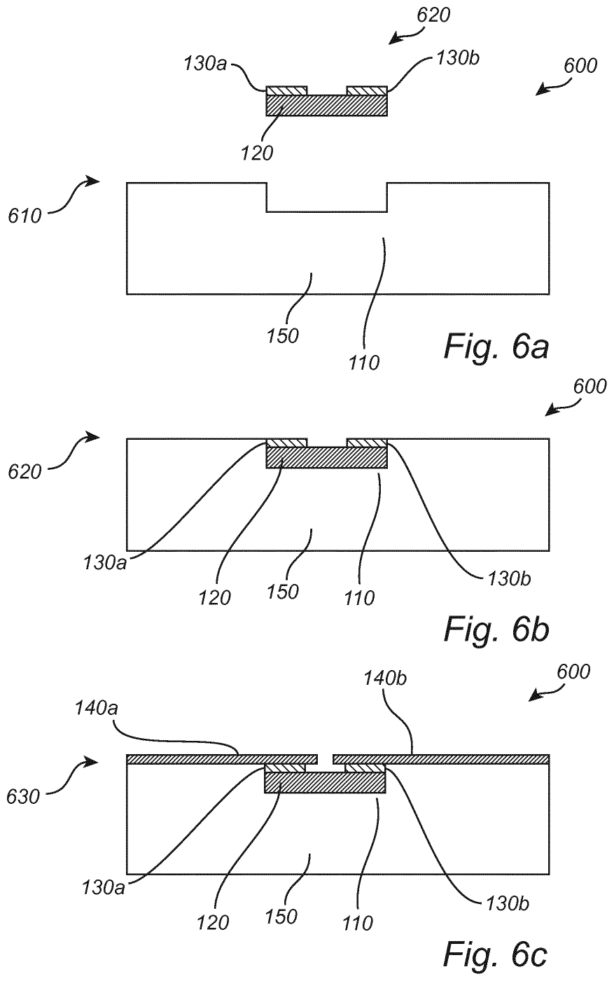

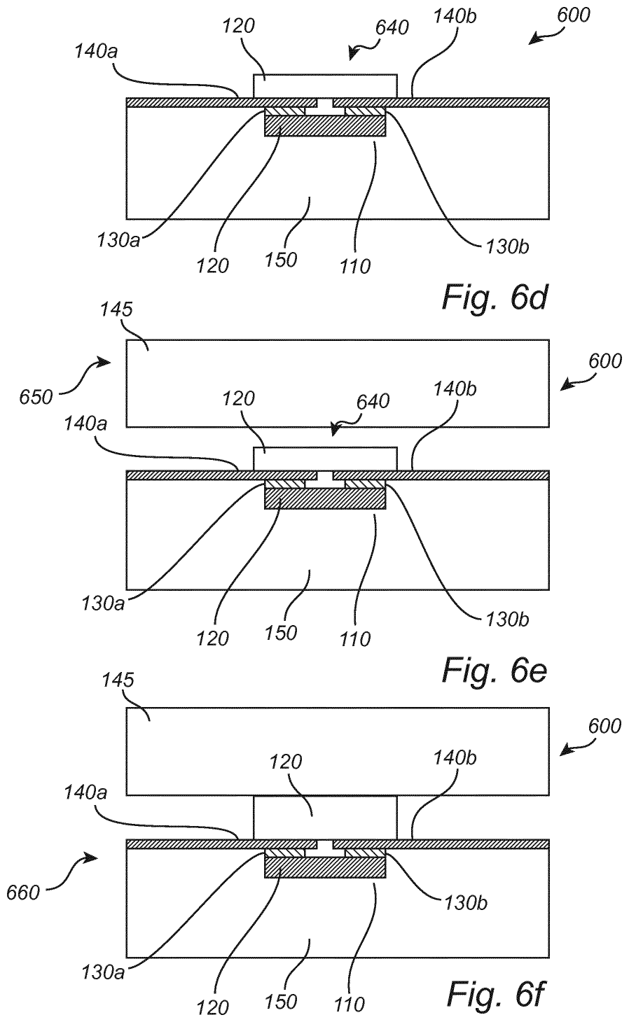

FIGS. 5a-f schematically show a method 500 of producing an electrical arrangement according to an embodiment of the present invention.

In FIG. 5a, the method 500 comprises printing 510 a first portion 150 of a substrate by a 3D-printing process, wherein the first portion 150 of the substrate is arranged to support at least one electrical element. The method 500 further comprises providing 520 at least one first part of at least one contractible component 200 at least partially within the first portion 150.

Furthermore, according to FIGS. 5a and 5b, the method 500 comprises arranging 530 an electrical element 120, comprising two electrical contact points 130a, 130b, at least partially within the first portion 150 of the substrate.

Shown in FIG. 5c, the method 500 further comprises printing 540, by a 3D-printing process, two electrically conductive tracks 140a, 140b arranged in contact with the respective electrical contact point 130a, 130b of the electrical element 120.

According to FIGS. 5d and 5e, the method 500 furthermore comprises printing 550 a second portion 160 of a substrate by a 3D-printing process, and arranging the second portion 160 at least partially upon the electrically conductive tracks 140a, 140b. The method 500 further comprises providing 560 a second part of the component 200 at least partially within the second portion 160, and connecting 570 the first and second parts of the component 200.

Furthermore, as shown in FIG. 5f, the method 500 further comprises processing 580 the contractible component 200 such that the electrical element 120 and the electrically conductive tracks 140a, 140b of the electrical unit 110 are squeezed at the respective electrical contact point 130a, 130b by the first 150 and second 160 portions of the substrate biased by the force from the component 200.

FIGS. 6a-f show, in a schematic manner, a method 600 of producing an electrical arrangement according to an embodiment of the present invention. According to FG. 6a, the method 600 comprises printing 610 a first portion 150 of a substrate by a 3D-printing process, wherein the first portion 150 of the substrate is arranged to support an electrical element. The method 600 further comprises arranging 620 an electrical element 120, comprising two electrical contact points 130a, 130b, at least partially within the first portion 150 of the substrate, shown in FIG. 6b.

Furthermore, according to FIG. 6c, the method comprises printing 630, by a 3D-printing process, two electrically conductive tracks 140a, 140b arranged in contact with the two electrical contact points 130a, 130b of the electrical element 120. Furthermore, shown in FIG. 6d, the method 600 comprises the step of arranging 640 an expandable component 120 at least partially upon the electrical element 120.

According to FIG. 6e, the method 600 further comprises the step of printing 650 a second portion 160 of a substrate by a 3D-printing process, and arranging the second portion 160 at least partially upon the component 120.

Moreover, shown in FIG. 6f, the method 600 comprises processing 660 the component 120 such that the electrical element 120 and the electrically conductive tracks 140a, 140b of the electrical unit 110 are squeezed at the respective electrical contact point 130a, 130b by the first 150 and second 160 portions biased by the force from the component 120. It will be appreciated that the first 150 and second 160 portions of the substrate may be mechanically connected (not shown).

The person skilled in the art realizes that the present invention by no means is limited to the preferred embodiments described above. On the contrary, many modifications and variations are possible within the scope of the appended claims. For example, it will be appreciated that the figures are merely schematic views of electrical arrangements according to embodiments of the present invention. Hence, any elements/components of the electrical arrangements 100 such as the component(s) 200, the substrate, etc., may have different dimensions, shapes and/or sizes than those depicted and/or described.

1. A method of producing an electrical arrangement, wherein the method comprises the steps of:
printing, by a 3D-printing process, a first portion of a substrate, wherein the first portion of the substrate is arranged to support at least one electrical element,
providing at least one first part of at least one component at least partially within the first portion, wherein the at least one component comprises a material that is contractible upon processing of the material,
arranging at least one electrical element, comprising at least one electrical contact point, at least partially within the first portion of the substrate,
printing, by a 3D-printing process, at least one electrically conductive track arranged in contact with the at least one electrical contact point of the at least one electrical element,
printing, by a 3D-printing process, a second portion of a substrate, and arranging the second portion at least partially upon the at least one electrically conductive track,
providing at least one second part of the at least one component at least partially within the second portion,
connecting the first and second parts of the at least one component, and
processing the at least one component such that the at least one electrical element and the at least one electrically conductive track are squeezed at the respective electrical contact point by the first and second portions biased by a force resulting from the contraction of the material of the at least one component.

2. A method of producing an electrical arrangement, wherein the method comprises the steps of:
printing, by a 3D-printing process, a first portion of a substrate, wherein the first portion of the substrate is arranged to support at least one electrical element,
arranging at least one electrical element, comprising at least one electrical contact point, at least partially within the first portion of the substrate,
printing, by a 3D-printing process, at least one electrically conductive track arranged in contact with the at least one electrical contact point of the at least one electrical element,
arranging at least one component at least partially upon the at least one electrical element, wherein the at least one component comprises a material that is expandable upon processing of the material,
printing, by a 3D-printing process, a second portion of a substrate, and arranging the second portion at least partially upon the at least one component,
arranging the first and second portions such that upon processing the at least one component the first and second portions become biased by a force resulting from the expansion of the material of the at least one component, and
processing the at least one component such that the at least one electrical element and the at least one electrically conductive track are squeezed at the respective electrical contact point by the first and second portions biased by the force resulting from the expansion of the material of the at least one component.

3. The method of claim 1, wherein the step of processing the at least one component comprises at least one of
a cooling of the at least one component, and
a polymerization of the at least one component.

4. An electrical arrangement obtainable by the method of claim 1, wherein the electrical arrangement comprises:
at least one electrical unit,
a substrate supporting the at least one electrical unit, wherein the substrate comprises a first portion and a second portion arranged on opposite sides, respectively, of the at least one electrical unit, and
at least one component for connecting the first portion and the second portion,
wherein the at least one electrical unit comprises
at least one electrical element having at least one electrical contact point, and
at least one electrically conductive track contacting the at least one electrical contact point,
wherein the at least one component comprises a material that is obtainable by processing a resizable material,
wherein, either the at least one component is in contact with the first portion and the second portion, and the material of the component is obtainable by processing a contractible material, or
the at least one component is in contact with the at least one electrical unit, and with at least one of the first portion and the second portion, and the material of the component is obtainable by processing an expandable material,
such that at least one of the at least one electrical element and the at least one electrically conductive track are squeezed at the respective electrical contact point by the first portion and the second portion biased by a force from the at least one component, wherein the force is obtainable by processing the resizeable material.

5. The electrical arrangement of claim 4, wherein the resizable material is contractible.

6. The electrical arrangement of claim 5, wherein the substrate comprises a first material having at least one of a first melting temperature (Tₘ₁) and a first glass transition temperature (T_{g1}), and the at least one component comprises a second material having at least one of a second melting temperature (Tₘ₂) and a second glass transition temperature (T_{g2}), wherein Tₘ₁>Tₘ₂, Tₘ₁>T_{g2}, T_{g1}>Tₘ₂ and T_{g1}>T_{g2}.

7. The electrical arrangement of claim 5, wherein the first and second portions are arranged along an axis (z), and wherein, for each electrical unit, at least one component is provided adjacent the electrical unit along an axis (x) perpendicular to the first axis (z).

8. The electrical arrangement of claim 7, wherein only one component is provided adjacent each electrical unit.

9. The electrical arrangement of claim 7, wherein at least one component is provided adjacent each electrical unit and on either side of each electrical unit.

10. The electrical arrangement of claim 7, wherein at least one of the at least one component protrudes the substrate and has the shape of a barbell, arranged to squeeze the first and second portions of the substrate.

11. The electrical arrangement of claim 7, wherein at least one of the at least one component is shaped as a staple which is arranged to squeeze the first and second portions of the substrate.

12. The electrical arrangement of claim 4, wherein the material of the at least one component is expandable.

13. A 3D-printing apparatus, comprising
a first printing material,
a second printing material,
and at least one printer head, configured to deposit the first printing material and the second printing material,
wherein the at least one printer head is configured to construct the substrate of the electrical arrangement of claim 4 by depositing at least a portion of the first printing material,
and wherein the at least one printer head is configured to construct the at least one component of the electrical arrangement by depositing at least a portion of the second printing material, and
wherein the second material of the at least one component is resizeable upon processing of the second material, such that upon a processing of the substrate and the at least one component, the at least one component is configured to resize to a higher extent than the substrate.

14. A computer program product comprising instructions which, when the computer program product is executed by the 3D printing apparatus according to claim 13, cause the 3D printing apparatus to carry out the method.
